(19) United States
(12) Patent Application Publication
(10) Pub. No.: US 2009/0029537 A1
(43) Pub. Date: Jan. 29, 2009

(54) Method for forming semiconductor package and mold cast used for the same

(75) Inventors: Chih Tai Hsu, Chieh Lung City (TW); Chung Ju Wu, Kao Hsiung City (TW); Chung Yin Fang, Hsin Chu City (TW)

Correspondence Address: Joe McKinney Muncy, PO Box 1364, Fairfax, VA, 22038-1364, US

(73) Assignee: SILICON INTEGRATED SYSTEMS CORP.

(21) Appl. No.: 11/878,731

(22) Filed: Jul. 26, 2007

(51) Int. Cl. H01L 21/20

(52) U.S. Cl. 438/584; 118/64; 257/E21.09

(57) ABSTRACT

A method for fabricating a thermally enhanced semiconductor package including the steps of providing a substrate having a first surface and a second surface; providing a die on the first surface of the substrate and electrically connecting the die with the substrate; placing the die, the substrate, and a heat slug in a mold cavity defined by a mold cast, the mold cast having a protruding portion that touches the periphery on the surface of the heat slug, wherein the contact area is defined as a periphery region and the non-contact area enclosed by the periphery region is defined as a central region; and encapsulating the die and the heat slug by molding materials, wherein the periphery region and the central region of the heat slug are exposed to the ambient air.

### BACKGROUND OF THE INVENTION

(a) Field of the Invention

The invention relates to a fabrication method and a mold cast for forming a semiconductor package, and particularly to a fabrication method and a mold cast for forming a thermally enhanced semiconductor package.

(b) Description of the Related Art

Nowadays, electronic products become light, thinner, and versatile because of the evolution of the integrated circuit fabrication technology. Further, because the ball grid array (BGA) package may provide high-density mounting and multiple contacts to reduce the layout areas for electrical components, it becomes the mainstream technology for IC packaging. However, as the mounting density is higher, it becomes more important about how to effectively dissipate the heat generated as a result of the operations of electrical components.

FIG. 1 shows a schematic diagram illustrating a conventional thermally enhanced plastic ball grid array (TEPBGA) package that has high heat dissipation efficiency. Referring to FIG. 1, a die 12 is attached on a substrate 11 and electrically connected thereto through bonding wires 13, and then the die 12 and a heat slug 14 are packed together and encapsulated by molding materials 15. Further, a plurality of solder balls 16 are mounted in SMT (Surface Mount Technology) on the bottom of the substrate 11 to electrically connect the package with an external device. During the molding process, the entire top surface 141 of the heat slug 14 is evenly covered by the inner surface of the mold cast 2, and, after the mold cast 2 is removed, the entire top surface 141 of the heat slug 14 not covered by the molding materials 15 is exposed to the ambient air. Thus, heat is effectively removed through the exposed surface 141 of the heat slug 14.

However, in the conventional design, since the contact surfaces of the mold cast 2 and the heat slug 14 are not perfectly flat, the heat slug 14 fails to be complete contact with the mold cast 2. Thus, the molding materials 15 are liable to permeate into tiny gaps between them to result in adverse overflow of molding materials 15. More specifically, FIG. 1B shows a normal semiconductor package without the adverse overflow of molding materials 15, where the exposed surface 141 of the heat slug 14 occupies a circular region. In comparison, FIG. 1C shows an inferior semiconductor package where the molding materials slope over the edge of the circular exposed surface 141. It can be clearly seen form FIG. 1C the splashes df of molding materials severely spoil the appearance of a finish product.

### BRIEF SUMMARY OF THE INVENTION

Hence, an object of the invention is to provide a fabrication method and a mold cast for forming a thermally enhanced semiconductor package without adverse overflow of molding materials.

According to one embodiment of the invention, a method for fabricating a thermally enhanced semiconductor package including the steps of providing a substrate having a first surface and a second surface; providing a die on the first surface of the substrate and electrically connecting the die with the substrate; placing the die, the substrate, and a heat slug in a mold cavity defined by a mold cast, the mold cast having a protruding portion that touches the periphery of one surface of the heat slug, wherein the area on the heat slug in contact with the protruding portion is defined as a periphery region, and the area on the heat slug not in contact with the protruding portion and enclosed by the periphery region is defined as a central region; and encapsulating the die and the heat slug by molding materials, wherein the periphery region and the central region of the heat slug are exposed to the ambient air.

Another embodiment of the invention regards a mold cast used for forming a thermally enhanced semiconductor package. The thermally enhanced semiconductor package comprises a substrate, a die provided on the substrate and electrically connected thereto, a heat slug provided on the substrate at the same side as the die, and molding materials for encapsulating the die and the heat slug, with part of the heat slug being exposed to the ambient air to form an exposed surface that includes a periphery region and a central region enclosed by the periphery region. The mold cast is characterized in that, during the molding process, the mold cast is in contact with only the periphery region and surrounds the central region of the exposed surface.

Through the design of the invention, since the contact area between the mold cast and the heat slug is restricted to allow for enhanced normal pressure, the heat slug is more closely attached on the mold cast to prevent molding materials from sloping over the gap between them. In addition, such design may cooperate with the operations of gas filling or air extraction to effectively prevent the overflow of molding materials and maintain fine appearance of a finished product.

These and other embodiments, aspects, advantages, and features of the present invention will be set forth in part in the description which follows, and in part will become apparent to those skilled in the art by reference to the following description of the invention and referenced drawings or by practice of the invention. The aspects, advantages, and features of the invention are realized and attained by means of the instrumentalities, procedures, and combinations particularly pointed out in the appended claims.

### BRIEF DESCRIPTION OF THE DRAWINGS

FIG. 1 shows a schematic diagram illustrating a conventional thermally enhanced plastic ball grid array (TEPBGA) package.

FIG. 1B and FIG. 1C show schematic diagrams illustrating the adverse overflow of molding materials

FIG. 2 shows a cross-section illustrating a thermally enhanced semiconductor package and a mold cast mounted on the package.

FIG. 3 shows a top plan view of a mold cast.

FIG. 4 shows a schematic diagram illustrating another embodiment of the invention.

FIG. 5 shows a schematic diagram illustrating another embodiment of the invention.

FIG. 6 shows a schematic diagram illustrating another embodiment of the invention.

FIG. 7 shows a schematic diagram illustrating another embodiment of the invention.

FIG. 8A shows a schematic diagram illustrating another embodiment of the invention.

FIG. 8B shows a schematic diagram illustrating another embodiment of the invention.

FIG. 9 shows a flowchart illustrating a method for fabricating a thermally enhanced semiconductor package of the invention.

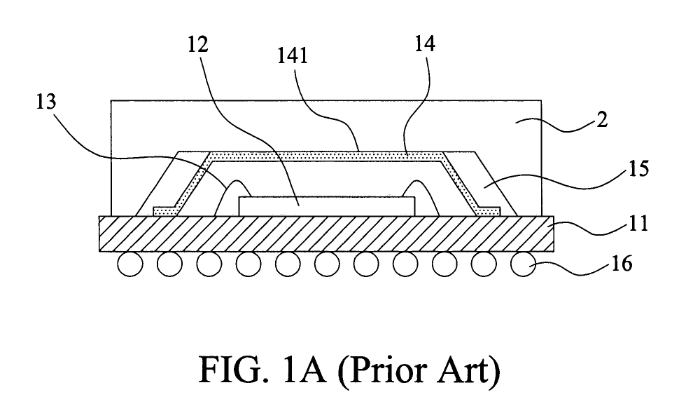

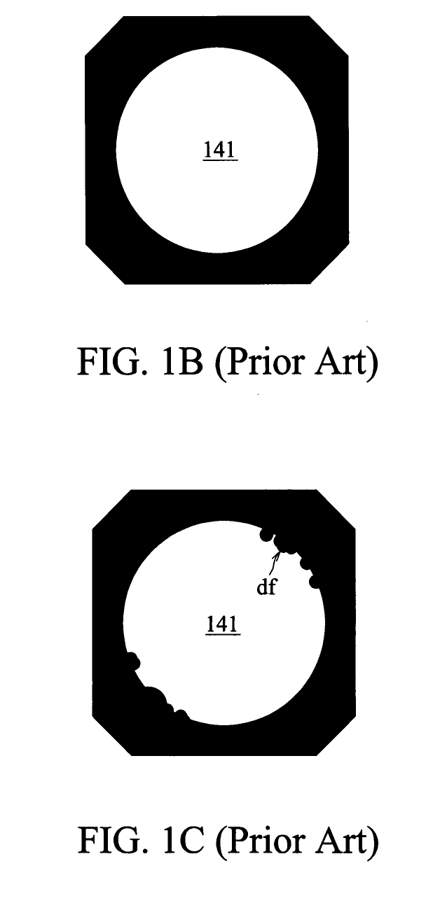

### DETAILED DESCRIPTION OF THE INVENTION

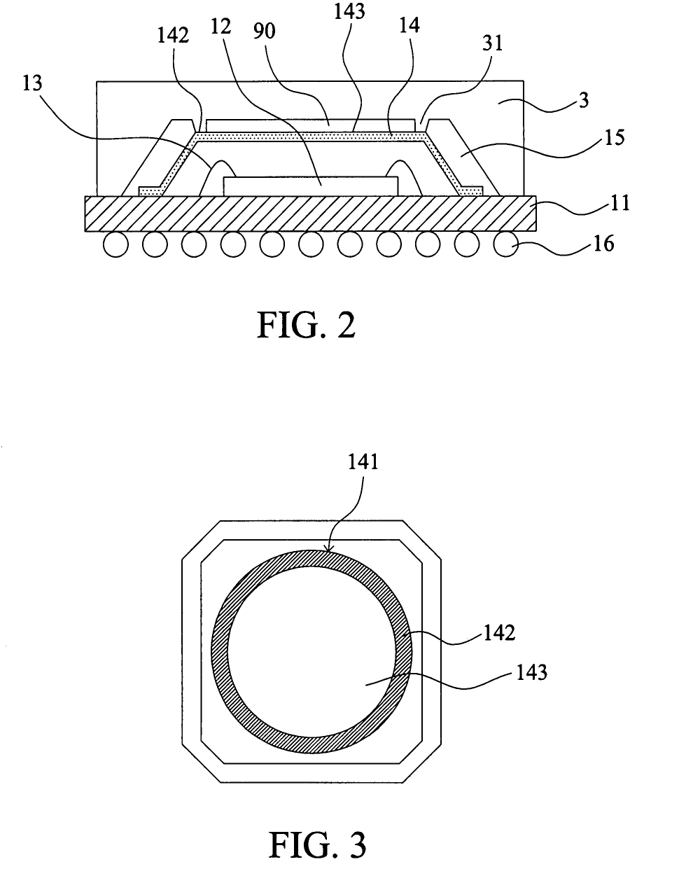

FIG. 2 shows a cross-section illustrating a thermally enhanced semiconductor package and a mold cast mounted on the package, and FIG. 3 shows a top plan view of the mold cast. Referring to FIG. 2, a die 12 that has an active face and a rear face opposite to the active face is adhered to the substrate 11 via its rear face, and the active face of the die 12 is electrically connected to the substrate 11 via bonding wires 13. Then, the assembly together with a heat slug 14 is placed in a mold cavity defined by a mold cast 3. The heat slug 14 may be made of metal such as copper having high thermal conductivity.

As shown in FIG. 2, the mold cast 3 has a protruding portion 31 that touches the periphery of the top surface of the heat slug 14, so the contact area of the top surface is defined as a periphery region 142 and the non-contact area enclosed by the periphery region 142 is defined as a central region 143. Since the mold cast 3 has a protruding portion 31, the heat slug 14 is limited to be in contact with the mold cast 3 in the periphery region 142. In this embodiment, the protruding portion 31 has an annular shape, and a gap 90 is formed between the mold cast 3 and the closed central region 143 of the top surface of the heat slug 14. During the molding process, the protruding portion 31 blocks the molding materials 15 to prevent them from flowing into the closed central region 143. Hence, after the mold cast 3 is removed, the periphery region 142 and the central region 143 of the heat slug 14 are not covered with the molding materials and are exposed to the ambient air to form an exposed surface 141.

In this embodiment, since only part of the mold cast 3, the protruding portion 31, touches the heat slug 14, the smaller contact areas there-between may cause a larger normal pressure that allows for rigid contact between the mold cast 3 and the heat slug 14, as compared with the conventional design where the entire top surface of the heat slug is covered by the mold cast. Besides, since the heat slug 14 touches only a small region instead of the entire surface of the mold cast 3, the mold cast 3 is in rigid contact with the heat slug 14 even the flatness of the heat slug 14 is inferior. For example, in case the central region 143 of the heat slug 14 is not flat, the mold cast 3 may be still in rigid contact with the heat slug 14 at the periphery region 142.

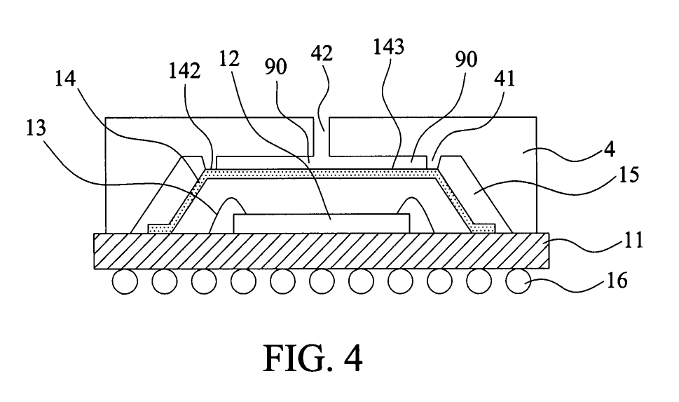

FIG. 4 shows a schematic diagram illustrating another embodiment of the invention. Referring to FIG. 4, this embodiment is similar to that shown in FIG. 2, except the mold cast 4 is additionally provided with a through hole 42 on the central region 143. Thereby, the heated air in the gap 90 is discharged via the through hole 42 to prevent the thermal-expanded air from lowering the closeness between the mold cast 4 and the heat slug 14.

Note that one can extract the air in the gap 90 via the through hole 42 to allow for more rigid contact between the mold cast 4 and the heat slug 14. On the other hand, one can fill gas into the gap 90 to maintain a positive pressure (the pressure in the gap 90 is slightly larger than the flow pressure of molding materials 15) so as to prevent molding materials 15 from sloping over the periphery region 142 under unsatisfied closeness between the mold cast 4 and the heat slug 14.

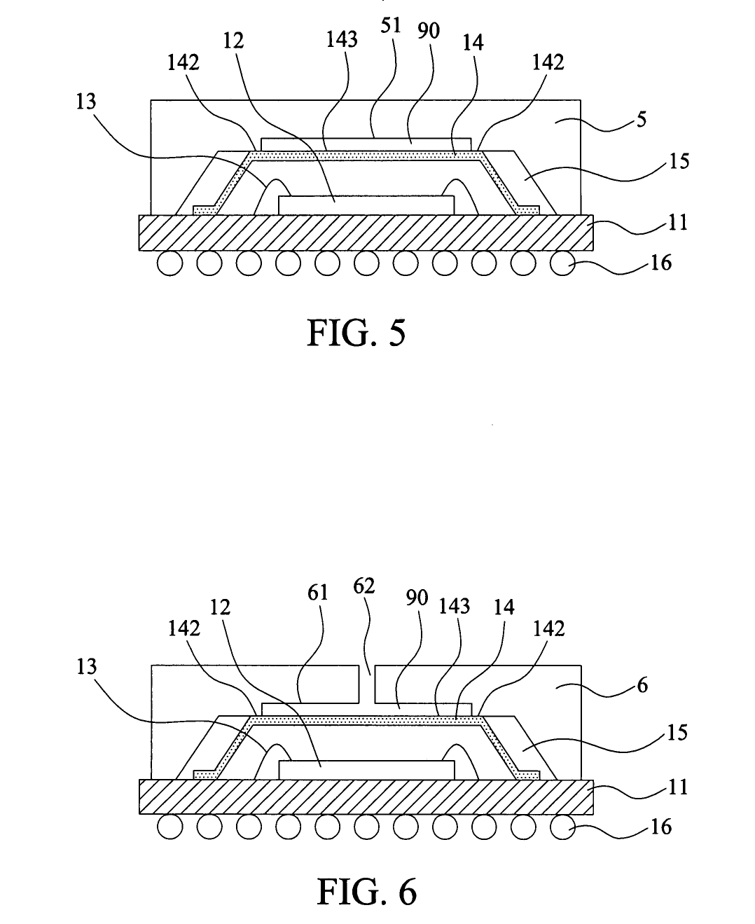

FIG. 5 shows a schematic diagram illustrating another embodiment of the invention. Referring to FIG. 5, a recess 51 is formed on the mold cast 5 at its one side adjacent to the heat slug 14 and overlaps the central region 143 of the heat slug 14, so that the periphery region 142 but not the central region 143 of the heat slug 14 touches the mold cast 5. According to this embodiment, the smaller contact areas similarly cause a larger normal pressure to allow for more close contact between the mold cast 5 and the heat slug 14. Further, as shown in FIG. 6, the mold cast 6 having a recess 61 may be additionally provided with a through hole 62 to achieve the same effects described in the aforesaid embodiments.

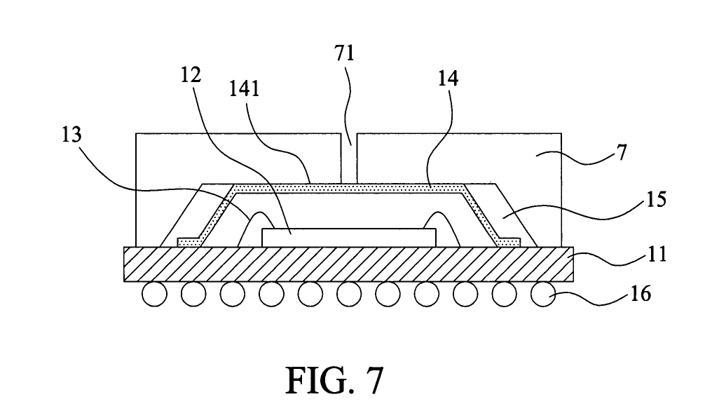

FIG. 7 shows a schematic diagram illustrating another embodiment of the invention. Referring to FIG. 7, the mold cast 7 is pierced to from a through hole 71 that penetrates through the portion of the mold cast 7 lying on the heat slug 14. Thus, one can extract the air in the assembly via the through hole 71 to allow for a more close contact between the mold cast 7 and the heat slug 14 to prevent molding materials 15 from sloping over the interface between the mold cast 7 and the heat slug 14. Further, in this embodiment, a die 12 is placed on a first surface of the substrate 11, and the active face of the die 12 is electrically connected to the substrate 11 via bonding wires 13. Then, the assembly and a heat slug 14 are packed together, and a plurality of solder balls 16 are mounted in SMT (Surface Mount Technology) on a second surface of the substrate 11 to achieve electrical connections with an external device. Note that such design may also be used in flip-chip packaging, where the active face of the die 12 is adhered on the first surface of the substrate 11 and electrically connected with the substrate 11 through solder bumps.

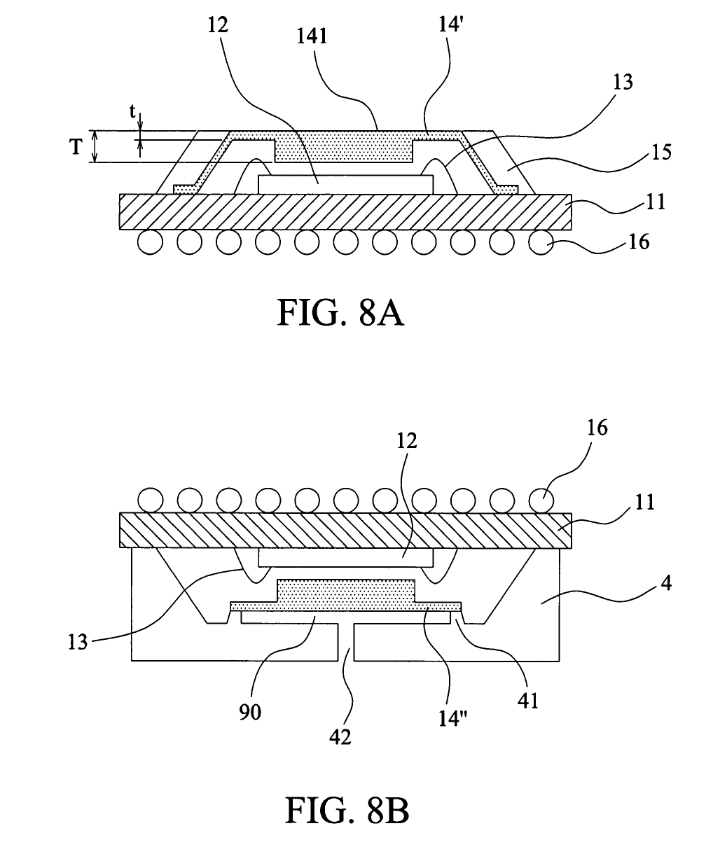

Note that the heat slug used in the invention is not limited to a specific type. As shown in FIG. 8A, the part of a heat slug 14′ overlapping the die 12 has a thickness T larger than a thickness t of its remainder parts to result in a smaller distance between the heat slug 14′ and the die 12 so as to enhance heat dissipation efficiency. Besides, the supporting arms of the heat slug 14′ which are connected to the substrate 11 can be omitted and, as shown in FIG. 8B, the heat slug 14″ without the supporting arms are not adhere to the substrate and are directly packed together with the die 12. Further, the heat slug 14″ is suitable for batch production; that is, multiple dies are arranged in succession on a continually extended substrate and equipped with multiple heat slugs 14″ that are connected with each other, and the substrate is split to form respective single die package. In addition, a surface treatment for increasing roughness may be performed on the exposed surface of the heat slug to improve the bonding strength between the heat slug and the molding materials.

Through the design of the invention, since the contact area between the mold cast and the heat slug is restricted to allow for enhanced normal pressure, the heat slug is more closely attached on the mold cast to prevent molding materials from sloping over the gap between them. In addition, such design may cooperate with the operations of gas filling or air extraction to effectively prevent the overflow of molding materials and maintain fine appearance of a finished product.

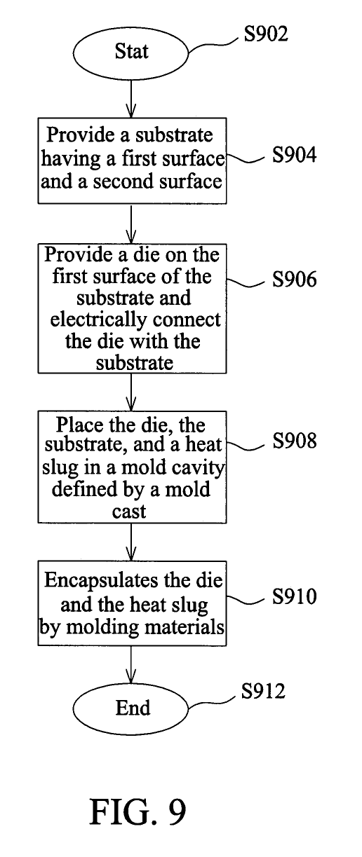

FIG. 9 shows a flowchart illustrating a method for fabricating a thermally enhanced semiconductor package. The method includes the steps described below.

Step S902: Start.

Step S904: Provide a substrate having a first surface and a second surface.

Step S906: Provide a die on the first surface of the substrate and electrically connect the die with the substrate, wherein the die has an active face and a rear face opposite to the active face, and the die is adhered to the substrate via its rear face and electrically connected to the substrate through bonding wires, or the die is adhered to the substrate via its active face and electrically connected to the substrate through solder bumps.

Step S908: Place the die, the substrate, and a heat slug in a mold cavity defined by a mold cast, the mold cast having a protruding portion that touches the periphery of one surface of the heat slug, wherein the area on the heat slug in contact with the protruding portion is defined as a periphery region, and the area on the heat slug not in contact with the protruding portion and enclosed by the periphery region is defined as a central region, wherein, the mold cast may be provided with a recess formed at a position overlapping the central region, or may be provided with at least one through hole that locates over the central region of the heat slug. Further, the heat slug may have at least supporting arm use to position the heat slug on the substrate, the part of the heat slug overlapping the die may have a thickness larger than the thickness of its remainder parts, and the heat slug is made of metal such as copper.

Step S910: Encapsulates the die and the heat slug by molding materials, wherein the periphery region and the central region of the heat slug are exposed to the ambient air.

Step S912: End.

While the invention has been described by way of example and in terms of the preferred embodiments, it is to be understood that the invention is not limited to the disclosed embodiments. For example, the fabrication method may further comprises the step of filling gas into the semiconductor package via the through hole to keep the pressure in the gap between the mold cast and the heat slug larger than the flow pressure of the molding materials; or further comprises the step of extracting the air in the semiconductor package via the through hole; or further comprises the step of forming a plurality of solder balls on the second surface of the substrate; or further comprises the step of performing a surface treatment on the heat slug to roughen the periphery region and the central region of the heat slug.

While the invention has been described by way of examples and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for fabricating a thermally enhanced semiconductor package, comprising the steps of:
providing a substrate having a first surface and a second surface;
providing a die on the first surface of the substrate and electrically connecting the die with the substrate;
placing the die, the substrate, and a heat slug in a mold cavity defined by a mold cast, the mold cast having a protruding portion that touches the periphery of one surface of the heat slug, wherein the area on the heat slug in contact with the protruding portion is defined as a periphery region, and the area on the heat slug not in contact with the protruding portion and enclosed by the periphery region is defined as a central region; and
encapsulating the die and the heat slug by molding materials, wherein the periphery region and the central region of the heat slug are exposed to the ambient air.

2. The fabrication method as claimed in claim 1, wherein the mold cast is provided with a recess formed at a position overlapping the central region.

3. The fabrication method as claimed in claim 1, wherein the mold cast is provided with at least one through hole that locates over the central region of the heat slug.

4. The fabrication method as claimed in claim 3, further comprising the step of:
filling gas into the semiconductor package via the through hole to keep the pressure in the gap between the mold cast and the heat slug larger than the flow pressure of the molding materials.

5. The fabrication method as claimed in claim 3, further comprising the step of:
extracting the air in the semiconductor package via the through hole.

6. The fabrication method as claimed in claim 1, further comprising the step of:
forming a plurality of solder balls on the second surface of the substrate.

7. The fabrication method as claimed in claim 1, wherein the die has an active face and a rear face opposite to the active face, and the die is adhered to the substrate via its rear face and electrically connected to the substrate through bonding wires.

8. The fabrication method as claimed in claim 1, wherein the die has an active face and a rear face opposite to the active face, and the die is adhered to the substrate via its active face and electrically connected to the substrate through solder bumps.

9. The fabrication method as claimed in claim 1, wherein the heat slug has at least supporting arm use to position the heat slug on the substrate.

10. The fabrication method as claimed in claim 1, further comprising the step of:
performing a surface treatment on the heat slug to roughen the periphery region and the central region of the heat slug.

11. The fabrication method as claimed in claim 1, wherein the part of the heat slug overlapping the die has a thickness larger than the thickness of its remainder parts.

12. The fabrication method as claimed in claim 1, wherein the heat slug is made of metal.

13. The fabrication method as claimed in claim 1, wherein the heat slug is made of copper.

14. A mold cast used for forming a thermally enhanced semiconductor package, the thermally enhanced semiconductor package comprising a substrate, a die provided on the substrate and electrically connected thereto, a heat slug provided on the substrate at the same side as the die, and molding materials for encapsulating the die and the heat slug, with part of the heat slug being exposed to the ambient air to formed an exposed surface that include a periphery region and a central region enclosed by the periphery region;
wherein the mold cast is characterized in that, during the molding process, the mold cast is in contact with only the periphery region and surrounds the central region of the exposed surface.

15. The mold cast as claimed in claim 14, wherein the mold cast has a protruding portion that touches the periphery region of the exposed surface.

16. The mold cast as claimed in claim 14, wherein the mold cast is provided with a recess formed at a position overlapping the central region.

17. The mold cast as claimed in claim 14, wherein the mold cast is provided with at least one through hole that locates over the central region of the heat slug.

18. The mold cast as claimed in claim 17, wherein the through hole is used to perform the operation of gas filling or air extraction.
